(19) United States
(12) Patent Application Publication
(10) Pub. No.: US 2015/0101352 A1
(43) Pub. Date: Apr. 16, 2015

(54) SYSTEM FOR CONTROLLING THERMAL CONDUCTIVITY OF ELECTRONIC PARTS HOUSING

(71) Applicant: Hyundai Motor Company, Seoul (KR)

(72) Inventors: Jin Woo Kwak, Gyeongsan (KR); Kyong Hwa Song, Seoul (KR); Gyung Bok Kim, Seoul (KR); In Chang Chu, Seoul (KR)

(73) Assignee: HYUNDAI MOTOR COMPANY, Seoul (KR)

(21) Appl. No.: 14/103,194

(22) Filed: Dec. 11, 2013

(30) Foreign Application Priority Data
Oct. 15, 2013 (KR) 10-2013-0122480

(51) Int. Cl. H05K 7/20

(52) U.S. Cl. CPC H05K 7/2039
USPC 62/3.1

(57) ABSTRACT

A system for controlling thermal conductivity of a housing of an electronic part is provided. In particular, liquid is disposed within a hollow portion formed between an external wall body and an internal wall body of the housing and a magnetic field generating member is attached to an outer surface of the internal wall body. Insulating magnetic particles are dispersed in the liquid, and an orientation of the insulating magnetic particles is changed according to a direction of a magnetic field applied by the magnetic field generating member. This, as a result, controls the thermal conductivity of the housing.

### CROSS-REFERENCE TO RELATED APPLICATION

This application claims priority under 35 U.S.C. §119 to Korean Patent Application No. 10-2013-0122480, filed on Oct. 15, 2013, in the Korean Intellectual Property Office, the disclosure of which is incorporated herein by reference in its entirety.

### BACKGROUND

(a) Technical Field

The present disclosure relates to a system for controlling thermal conductivity of a housing of an electronic part to effectively control the thermal conductivity of the housing which accommodates the electronic part therein.

(b) Background Art

Recently, there is an increase in the number of electronic parts mounted in a vehicle and subsequently a large-scale integration thereof. Additionally, heat generation in a vehicle battery, one of main power electronic parts, has been emerging as a serious issue in vehicles.

Particularly, in an environment-friendly vehicle such as an electric vehicle or a hybrid vehicle, reliability and stability of a battery system are important factors in determining the vehicle marketability. Therefore, it is important to maintain the battery system in an appropriate temperature range in order to prevent battery performance degradation due to a change in outside temperature.

In general, it is known that the energy and output of a lithium-ion battery are rapidly degraded when temperature decreases to −10° C. or below. For example, regarding a lithium-ion battery such as the 18650 battery, it was reported that only 5% of the energy density and 1.25% of the output density can be transmitted in an environment at −40° C., as compared to an environment at 20° C. (G. Nagasubramanian, J Appl Electrochem, 31, 99. (2001)). In addition, it is reported that a lithium-ion battery can be normally discharged but cannot be charged properly in a low-temperature environment (C. K. Huang, J. S. Sakamoto, J. Wolfenstine and S. Surampudi, J. Electrochem. Soc. 147 (2000) 2893; S. S. Zhang, K. Xu and T. R. Jow, Electrochim. Acta 48(2002) 241).

It is also reported that the causes of performance degradation of the lithium-ion battery in a low-temperature environments are the degraded ion conductivity of an electrolyte, a solid electrolyte membrane formed on the surface of graphite, low diffusibility of lithium ions to graphite, an increase in charge transfer resistance at the interface between an electrolyte and an electrode, and the like (S. S. Zhang, K. Xu and T. R. Jow, J Power Sources 115, 137 (2003)). In order to solve these problems, additional heat insulation is typically needed for maintaining the temperature of the battery in an appropriate temperature range.

In addition, while the degradation of the output and performance of the battery in the low-temperature environment has emerged as a problem as described above, in an environment in which an actual operation temperature is a high temperature, a thermal runaway phenomenon of the battery also becomes a problem.

Therefore, to prevent the deterioration in battery performance due to various changes in outside temperature, the temperature of the battery system should be maintained in an appropriate temperature range. For this, a technique of maintaining the temperature of a battery system in an appropriate temperature range even in a low-temperature environment while having excellent heat dissipation performance is maintained in general weather conditions needs to be developed.

Particularly, in an environment-friendly vehicle such as an electric vehicle or a hybrid vehicle, since the battery is the main power source of the vehicle, the degradation of the output and performance of the battery directly results in the degradation of the performance of the vehicle. In the related art, in order to solve a heat generation problem in an electronic part for a vehicle, particularly, a battery system, research to form a housing using a composite material containing a filler having excellent thermal conductivity have been actively carried out.

However, the heat dissipation-type composite material according to the related art is limited to the improvement in thermal conductivity, and in a case of a housing manufactured by injection molding processes, thermal conductivity anisotropy occurs due to the orientation of the filler in an injection direction. Typically, the thermal conductivity in the thickness direction is about ⅓ to ¼ of the thermal conductivity in the injection direction and is thus very low.

For efficient heat dissipation, heat transfer paths suitable for the shape and properties of a housing part have to be formed to obtain excellent heat dissipation effect by convection, and most housings for electronic parts are produced to enhance heat transfer characteristics in the thickness direction so as to enhance heat dissipation efficiency.

In the case of a battery module, battery performance degradation occurs depending on the actual operation environment and temperature. In general, a thermal runaway phenomenon of the battery at a high temperature becomes a problem, and battery output degradation in a low-temperature environment has emerged as the most serious problem.

As such, heat control materials in the related art have focused only on improving thermal conductivity of the materials only from a viewpoint of heat dissipation, and in a case where heat insulation is needed, a housing has been manufactured by using additional foam or a plastic material having low thermal conductivity.

This may not actively cope with changing environments in which a single part needs both heat insulation and heat dissipation, and in the case of excellent heat insulation, a heat dissipation problem occurs and in the case of excellent heat dissipation, a heat insulation problem occurs due to high thermal conductivity.

That is, in the related art in order to solve the heat dissipation and heat insulation problems at the same time, the housing is made of an insulating material and then the capacity of a blower is increased or a water-cooling system (water-cooling type) is used to reinforce heat dissipation performance and solve the heat dissipation problem. However, these solutions result in an increase in the overall weight of the system.

In order to solve the problems in the related art, there is a demand for the development of a technique for varying/changing the thermal conductivity to control thermal conductivity depending on a surrounding environment, and a material having a varying thermal conductivity while at the same time having insulation properties is needed for electronic parts.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

The present invention provides a system for controlling thermal conductivity of a housing of an electronic part, capable of varying the thermal conductivity of the housing by controlling an orientation of insulating magnetic particles in a liquid that fills a hollow portion of the housing of the electronic part.

In one aspect, the present invention provides a system for controlling thermal conductivity of a housing of an electronic part, including: in order to control the thermal conductivity of the housing for the electronic part, a liquid which fills a hollow portion formed between an external wall body and an internal wall body of the housing; and a magnetic field generating member which is attached to an outer surface of the internal wall body, in which insulating magnetic particles are dispersed in the filling liquid, and an orientation of the insulating magnetic particles is changed according to a direction of a magnetic field applied by the magnetic field generating member, thereby controlling the thermal conductivity of the housing.

In an exemplary embodiment, the system for controlling thermal conductivity of a housing of an electronic part may further include a current supply unit for applying current to the magnetic field generating member. The current supply unit may apply the current in a forward direction to orient the insulating magnetic particles or may apply the current in a reverse direction to release or change the orientation of the insulating magnetic particles.

In another exemplary embodiment, as the magnetic field generating member, one selected from a group consisting of a winding type solenoid, a linear type solenoid, and a loop type solenoid may be used, or two or more thereof may be simultaneously used.

In still another exemplary embodiment, the insulating magnetic particles may be ellipsoidal magnetic particles coated with electrical insulation-type thermal conductive particles on their surfaces.

In yet another exemplary embodiment, the filling liquid may be a silicone oil, and the insulating magnetic particles may be made by coating surfaces of any one selected from a group consisting of ion (Fe), cobalt (Co), and nickel (Ni) with any one selected from a group consisting boron nitride, alumina, and magnesium oxide.

Advantageously, the system for controlling thermal conductivity of a housing of an electronic part according to the present disclosure can control the thermal conductivity of the housing of the electronic part to vary depending on a surrounding environment by applying the magnetic field to the liquid within a hollow portion of the housing of the electronic part, and accordingly, ensures durability and stability against the temperature of the electronic part without an additional heating device.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a diagram illustrating a system for controlling thermal conductivity of a housing of an electronic part according to an exemplary embodiment of the present disclosure;

FIG. 2 is an enlarged view of the “A” part of FIG. 1 and is a diagram illustrating an orientation of insulating magnetic particles in a filling liquid by a magnetic field according to an exemplary embodiment of the present disclosure;

FIG. 3 is a diagram illustrating directions in which the magnetic field is formed by a magnetic field generating member according to an exemplary embodiment of the present disclosure; and

FIGS. 4 to 6 are diagrams illustrating types of solenoids used in the system for controlling thermal conductivity of a housing of an electronic part according to an exemplary embodiment of the present disclosure.

Reference numerals set forth in the Drawings includes reference to the following elements as further discussed below:

| | |
|---|---|
| 1: housing | 2: external wall body |
| 3: internal wall body | 4: filler |
| 5: magnetic field generating member | |

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, the present disclosure will be described so as to be easily embodied by those skilled in the art.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present disclosure relates to a system for controlling thermal conductivity of a housing of an electronic part, and the thermal conductivity of the housing can be controlled to vary by controlling the orientation of filler in a liquid within a hollow portion of the housing of the electronic part.

Particularly, in the present disclosure, in order to fundamentally solve performance degradation due to a surrounding temperature, heat generation, and the like of the electronic part such as a battery module of an environment-friendly vehicle, formation of heat transfer paths is adjusted and controlled by using the orientation of insulating magnetic particles which are a within a filler liquid within a hollow portion of the housing. That is, ellipsoidal magnetic particles coated with electrical insulation-type thermal conductive particles on their surfaces in a magnetic field are used to change the thermodynamic properties of the material and accordingly provide heat insulation or heat dissipation depending upon the surrounding environment.

According to the present invention, the thermal conduction properties of the housing can be changed by changing the orientation of the insulating magnetic particles according to the direction of the magnetic field applied to the hollow portion of the housing of the electronic part, and heat dissipation performance and heat insulation performance of the housing can be selectively imparted when the direction of the magnetic field applied to the hollow portion is controlled according to a heat generation state of the electronic part accommodated in the housing or a surrounding temperature.

Therefore, in the present disclosure, the liquid in which the insulating magnetic particles are dispersed and a magnetic field generating member which generates a magnetic field for controlling the orientation of the insulating magnetic particles dispersed in the liquid are disposed in the housing of the electronic part.

Here, as the magnetic field generating member, various shapes of solenoids can be used, and the installation posture and the position of the solenoid may be set in consideration of the direction of magnetic flux formed according to the shape of the solenoid.

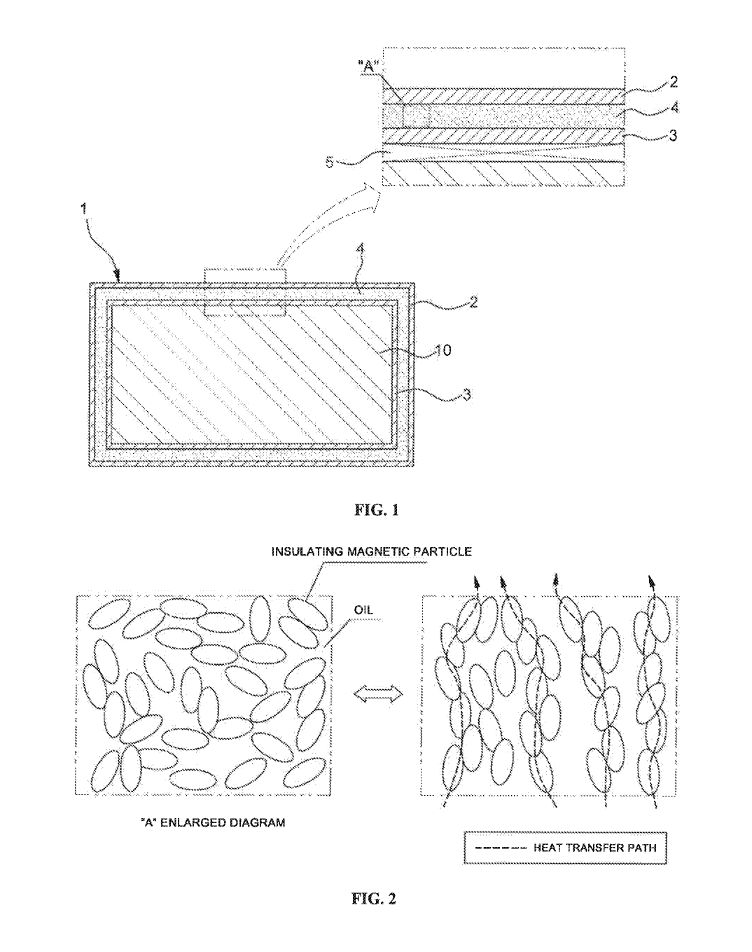

Referring to FIG. 1, the housing 1 may be implemented as a structure having a shape capable of enclosing and protecting the electronic part 10 mounted in a vehicle or the like. That is, the housing 1 accommodates the electronic part 10 to be protected from the outside in its internal space. Thus, the housing is not limited to any particular shape. In addition, the housing 1 may be manufactured by using a thermally conductive plastic material so as to enhance heat dissipation properties.

Here, the housing 1 may be molded using an engineering plastic that contains a thermal conductive filler so as to transfer heat generated by the electronic part 10 to the outside so as to be dissipated.

As an example, a plastic that contains the thermal conductive filler in a range of 30 to 60 weight % with respect to the plastic may be used. In this case, as a type of the thermal conductive filler, graphite or boron nitride formed as plate-like particles may be used. Otherwise, any type of thermal conductive filler may be employed as long as it can be dispersed in the plastic and molded while having thermal conduction properties.

In addition, the housing 1 is manufactured to have a structure with the hollow portion therein. The wall body of the housing 1 is formed to have a dual structure including an external wall body 2 and an internal wall body 3, and the hollow portion is provided between the external wall body 2 and the internal wall body 3.

Here, the hollow portion of the housing 1 has to be sealed after being filled with a liquid which contains the insulating magnetic particles (or in which the insulating magnetic particles are dispersed). In other words, the hollow portion of the housing 1 has to be sealed after being filled with a filler 4 made by mixing the insulating magnetic particles and the liquid. Therefore, the housing 4 may be manufactured to have a structure in which an open portion is provided on one side of the hollow portion and after filling the hollow portion with the filler 4, the hollow portion is sealed by assembling an additional wall body or the like.

In addition, ribs (not illustrated) may be formed between the external wall body 2 and the internal wall body 3 at intervals. At this time, by the ribs, the structural rigidity of the housing 1 can be reinforced, and the space of the hollow portion can be partitioned into a plurality of spaces.

For example, the hollow portion can be partitioned into several spaces using the ribs installed therein, and the rigidity of the housing can be controlled according to the shape, structure, position, and the like of the installed ribs. In addition, by changing the amount of insulating magnetic particles filling each of the partitioned spaces of the hollow portion, heat transfer efficiencies of the spaces may be varied.

Also, as the insulating magnetic particles in the filler 4 that fills the hollow portion of the housing 1, magnetic particles coated with electrical insulation-type thermal conductive particles are used, and as illustrated in FIG. 2, ellipsoidal magnetic particles may be used.

That is, as the insulating magnetic particles, “ellipsoidal magnetic particles coated with electrical insulation-type thermal conductive particles on their surfaces” are used. In a case where the ellipsoidal magnetic particles are used, as illustrated in the figure on the right of FIG. 2, compared to a case where circular magnetic particles are used, interparticle contact areas can be increased when a magnetic field is applied, which is advantageous to formation of three-dimensional heat transfer paths.

When the magnetic field is applied to the filler 4 in the hollow portion, the insulating magnetic particles are re-oriented in a magnetic flux direction. Since the ellipsoidal magnetic particles have magnetic anisotropy, the ellipsoidal magnetic particles can be oriented properly under the magnetic field, and thus a thermal conductivity change response to the magnetic field can be increased.

The filler 4 is made of the liquid in which the insulating magnetic particles are dispersed, and by controlling the orientation of the magnetic particles by applying the magnetic field in various methods, heat transfer paths can be formed in a desired direction.

In addition, the size of the insulating magnetic particle may be a micron-scale particle size, and should be preferably a particle size that enables micro-Brownian motion while being able to settle in the liquid (e.g., silicone oil). For this, the insulating magnetic particles may have a particle size in a range from about 0.1 to 10 μm.

In addition, as the magnetic particles, magnetic particles made of iron (Fe), cobalt (Co), nickel (Ni), or the like may be used. As the electrical insulation-type thermal conductive particles coated on the surfaces of the magnetic particles, thermal conductive particles made of boron nitride, alumina, magnesium oxide, or the like may be used.

The insulating magnetic particles have surface insulation properties by being coated with the electrical insulation-type thermal conductive particles on the surfaces of the magnetic particles, and thus enable the improvement in the thermal conductivity of the housing as an insulator.

That is, the coated layers of the magnetic particles made by being coated with the electrical insulation-type thermal conductive particles as described above have electrical insulation and heat conduction properties. Therefore, the insulating magnetic particles exhibit electrical insulation and heat conduction properties along with a property of being entirely oriented by the magnetic field.

Particularly, since the insulating magnetic particles themselves have thermal conduction properties, as illustrated in the figure on the right of FIG. 2, in a state where the magnetic particles are oriented in the filling liquid in the hollow portion, heat transfer paths may be formed by interparticle contact (heat transfer paths are formed in a direction in which the particles are oriented).

As the filling liquid, a liquid having an appropriate viscosity such as silicone oil, and desirably, a viscous liquid having electrical insulation properties may be used. A liquid having an appropriate viscosity and fluidity for the insulating magnetic particles in the liquid to be oriented by the magnetic field in a state of being dispersed is used.

The filler 4 that fills the hollow portion of the housing 1 is a smart material that can change the thermal conduction properties of the housing when being applied with an electric field.

For example, in a case where the heat dissipation performance of the housing of the electronic part needs to be improved in a relatively high temperature environment, an electric field is applied to the filler to orient the insulating magnetic particles and form the heat transfer paths, thereby increasing the thermal conductivity of the housing. In a case where the heat insulation function of the housing of the electronic part is needed in a relatively low temperature environment, the coercive force of the insulating magnetic particles is applied (e.g., current having the same value as that applied to orient the magnetic particles is applied in the reverse direction) to the filler so as to orient the insulating magnetic particles at random (or release the orientation thereof), thereby reducing the thermal conductivity of the housing and implementing the heat insulation function.

On the other hand, in order to apply the magnetic field to the filler 4 within the hollow portion of the housing 1, current is applied to the magnetic field generating member 5 such as a solenoid, and the orientation of the filler (e.g., the insulating magnetic particles) in the liquid may be controlled according to the type and shape of the solenoid. Accordingly, the heat transfer paths can be varied.

In addition, the content of the insulating magnetic particles in the filler 4 and the type of the liquid selected may influence the control and improvement in the thermal conductivity of the housing 1.

Referring to FIG. 1, the filler 4 and the magnetic field generating member 5 for applying the magnetic field to the insulating magnetic particles in the filler 4 are installed between the housing 1 which accommodates the electronic part 10 and the electronic part 10.

The magnetic field generating member 5 may be attached and installed on the outer surface (e.g., a wall surface opposing the electronic part accommodated in the internal space of the housing) of the internal wall body and generates the magnetic field in a predetermined direction when current is applied thereto to form a magnetic flux.

The magnetic field generating member 5 has to be installed at a position at which the magnetic field generated when current is applied can be applied to the filler within the hollow portion, and has to be installed at an appropriate position with an appropriate size in consideration of the direction of the magnetic field which is to be applied to the hollow portion during heat dissipation and heat insulation.

As illustrated in FIG. 1, the magnetic field generating member 5 may be attached and installed on the inner surface of the internal space of the housing 1 which accommodates the electronic part 10 (i.e., that is, the outer surface of the internal wall body). However, the magnetic field generating member 5 may also be installed at another position at which the magnetic field generated when current is applied can be applied to the insulating magnetic particles in the hollow portion, and if a structure that can insulate the magnetic field generating member 5 is employed, the magnetic field generating member 5 may also be installed inside the hollow portion.

The filler 4 that is disposed in the hollow portion of the housing 1 is a composite material made by mixing a continuous phase oil (i.e., the filling liquid) and the insulating magnetic particles dispersed in the oil, and when the magnetic field is generated by the magnetic field generating member 5, the insulating magnetic particles are oriented in one direction by magnetic force formed in a predetermined direction, or the orientation thereof is released by coercive force.

Here, the coercive force may be generated by applying current having the same value as that of the current applied to the magnetic field generating member 5 in the reverse direction so as to generate magnetic force for orienting the insulating magnetic particles.

The direction of current applied to the magnetic field generating member 5 is determined in consideration of the direction of magnetic flux generated by the magnetic field generating member 5 (the direction of the magnetic field), formation of the heat transfer paths by the orientation of the insulating magnetic particles, and the like.

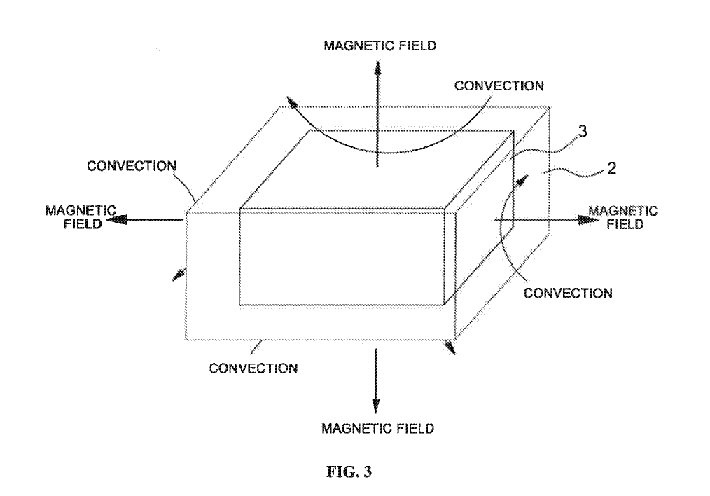

As illustrated in FIG. 2, in the case where the magnetic field is applied to the filler 4, the insulating magnetic particles dispersed in the continuous face silicone oil (the filling liquid) are oriented along the direction of magnetic flux and form the heat transfer paths. At this time, the magnetic flux may be formed in a direction toward the outside of the housing 2, and for example, may be formed in a direction orthogonal to the surface of the housing 2 as in FIG. 3.

Here, by controlling the installation posture and the position of the magnetic field generating member 5 installed in the housing 1, the magnetic flux generated by the magnetic field generating member 5 may be directed toward the outside of the housing 1. In addition, although not illustrated in the figure, a current supply unit (not illustrated) for applying current to the magnetic field generating member 5 is included.

The current supply unit is configured to be connected to the magnetic field generating member 5 so as to supply current thereto, and applies current in a forward direction (or current in the reverse direction) to induce the magnetic field to be generated in a predetermined direction in order to orient the insulating magnetic particles or applies current in the reverse direction (or current in the forward direction) to induce a coercive magnetic field to be generated so as to release or change the orientation of the insulating magnetic particles.

In this configuration, when the magnetic field is applied to the filler 4 in the hollow portion of the housing 1 for the electronic part by the magnetic field generating member 5, the orientation of the insulating magnetic particles is changed according to the direction of the magnetic field, thereby controlling the thermal conductivity of the housing. Particularly, according to the orientation characteristics of the insulating magnetic particles in the magnetic field, heat dissipation and heat insulation of the housing can be selectively performed.

More specifically, when current is applied to the magnetic field generating member 5 installed in the housing 1, the magnetic field is generated, and at the same time, the insulating magnetic particles are oriented in the vertical direction and form heat transfer paths as illustrated in the figure on the right of FIG. 2.

Particularly, since the heat dissipation performance and the heat insulation performance can be selectively imparted on the housing 1 depending on the direction of current that is applied to the magnetic field generating member 5, generation and interruption of the heat transfer paths can be selectively achieved as the magnetic field is generated depending on the direction of the current and the magnetic particles are moved along the direction of the magnetic field.

That is, when the heat dissipation performance of the housing 1 is needed due to the heat generation state of the electronic part 10 and a high surrounding temperature, the magnetic field is generated to be applied to the filler 4 in the hollow portion by applying current to the magnetic field generating member 5, and at the same time, the magnetic particles are oriented as illustrated in the figure on the right of FIG. 2. Therefore, heat transfer paths are formed by the oriented magnetic particles, thereby increasing thermal conductivity.

On the other hand, when the heat insulation performance of the housing 1 is needed in a low-temperature environment, current having the same value is applied to the magnetic field generating member 5 in the reverse direction to apply a coercive electric field to the magnetic particles. Therefore, the agnetic particles are oriented at random (interruption of heat transfer paths) to implement the heat insulation performance of the housing, thereby preventing the degradation of the performance of the electronic part 10.

As described above, the direction of current that is applied to the magnetic field generating member 5 is determined in consideration of the heat transfer paths due to the direction of the magnetic field and the orientation of the magnetic particles, and the heat dissipation or heat insulation performance demanded by the operational condition of the electronic part or surrounding environment conditions.

In addition, the winding direction of the magnetic field generating member 5 such as a solenoid is selected in consideration of the direction of the magnetic field generated by the magnetic field generating member 5.

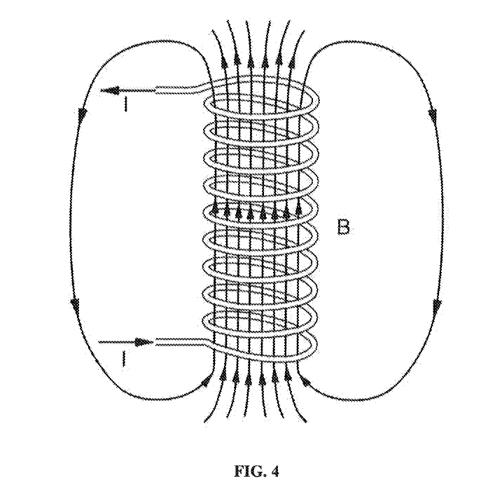

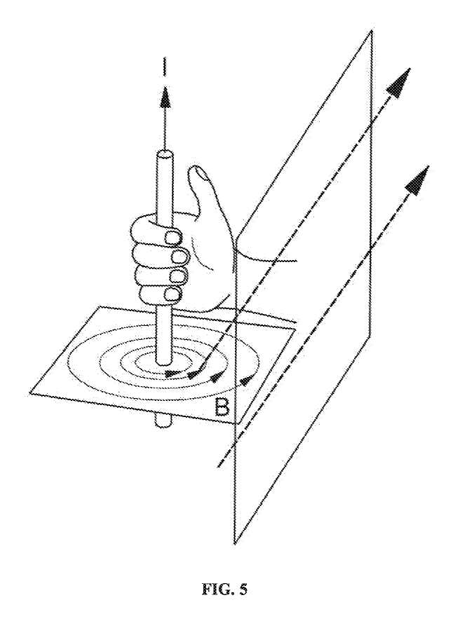

FIGS. 4 to 6 are diagrams illustrating directions of magnetic fields according to winding directions of solenoids and current being applied. As illustrated in FIGS. 4 to 6, solenoids may be wound in the forms of winding type, linear type, loop type, and the like to be used. That is, as the magnetic field generating member 5, a winding type solenoid, a linear type solenoid, a loop type solenoid, and the like may be used.

Referring to FIG. 4, the winding type solenoid forms magnetic flux and the like which penetrate through the center of the solenoid wound into a coil form in a substantially straight direction according to the Ampere's Right-hand rule. When the winding type solenoid is installed in the housing 1, the insulating magnetic particles in the filler 4 is oriented by the magnetic field that penetrates through the center portion of the solenoid.

In the case of the winding type solenoid, when being installed in the housing 1, for example, the winding type solenoid may be installed so that the magnetic field that penetrates through the center portion of the solenoid penetrates through each wall surface of the housing 1 (wall surface where the solenoid is installed) in an orthogonal direction.

Referring to FIG. 5, the linear type solenoid forms magnetic flux and the like in a pattern of a number of concentric circles on each vertical surface with respect to the linear type solenoid according to the Ampere's Right-hand rule. When the linear type solenoid is installed in the housing 1, the insulating magnetic particles in the filler 4 is oriented by the magnetic field in a tangential direction to the magnetic flux having the pattern of concentric circles.

In the case of the linear type solenoid, when being installed in the housing 1, for example, the linear type solenoid may be installed so that the magnetic field in the tangential direction penetrates through partial wall surfaces of the housing (wall surfaces adjacent to the wall surface where the solenoid is installed).

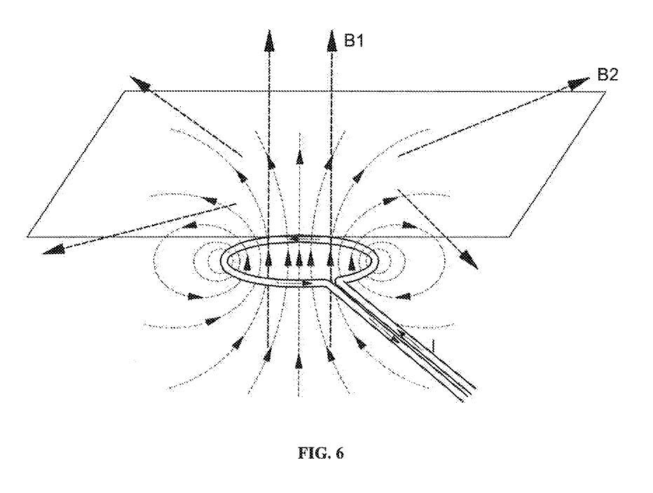

Referring to FIG. 6, the loop type solenoid forms a magnetic flux (B1) in a perpendicular direction to current that flows through the circular conducting wire in the loop type solenoid, and at the same time, forms a radial magnetic flux (B2) in a horizontal direction to the current that flows through the circular conducting wire. When the loop type solenoid is installed in the housing 1, the insulating magnetic particles in the filler 4 is oriented by the magnetic field (B1) in the perpendicular direction and the radial magnetic field (B2).

In the case of the loop type solenoid, when being installed in the housing 1, for example, the loop type solenoid may be installed so that the magnetic field (B1) in the perpendicular direction and the radial magnetic field (B2) penetrate through partial wall surfaces of the housing. At this time, most of the magnetic field (B1) in the perpendicular direction penetrates through the wall surface of the housing where the solenoid is installed in the orthogonal direction, and most of the radial magnetic field (B2) penetrates through the wall surfaces adjacent to the wall surface of the housing where the solenoid is installed. Particularly, in the case where the loop type solenoid is used, the surface of the housing 2 of the electronic part is coated with an additional magnetic material.

By coating the surface of the housing 1 for the electronic part with the magnetic material, the insulating magnetic particles are induced by the magnetic field of the solenoid to be radially oriented, thereby controlling the heat transfer paths.

For reference, in the case of the winding type, linear type, and loop type solenoids, the magnetic fields are formed in various directions according to the flow of the current, but the main magnetic field applied to the filler 4 in the hollow portion of the housing 1 is formed as described above.

In addition, the main magnetic field (the magnetic flux) generated by the magnetic field generating member 5 such as the solenoids and applied to the filler 4 in the hollow portion of the housing 1 is directed to the outside of the housing 1 as illustrated in FIG. 3, and the magnetic field generating member 5 is installed inside the housing 1 in consideration of the direction of the magnetic field. That is, in consideration of the direction of the magnetic field (magnetic flux) applied to the filler 4, the shape and positioning (the installation position and posture in the housing) of the solenoid that can be installed in the housing is selected.

In the present disclosure, when the heat transfer paths have to be controlled in consideration of the internal structure of the housing of the electronic part, the orientation of the insulating magnetic particles in the filler may be controlled by using various shapes of solenoids described above, and accordingly, the heat transfer paths may be formed.

Therefore, when there is a demand for heat dissipation of the housing material, the heat transfer paths are formed by orienting the insulating magnetic particles in the filler to enhance the thermal conductivity of the housing, and heat is dissipated from the surface of the housing through convection and air-cooling to prevent the performance degradation of the electronic part.

While the embodiment of the present disclosure has been described in detail, the scope of the right of the present disclosure is not limited to the above-described embodiment, and various modifications and improved forms by those skilled in the art who use the basic concept of the present disclosure defined in the appended claims also belong to the scope of the right of the present disclosure.

What is claimed is:

1. A system for controlling thermal conductivity of a housing of an electronic part, comprising:
a liquid disposed within a hollow portion formed between an external wall body and an internal wall body of the housing; and
a magnetic field generating member attached to an outer surface of the internal wall body of the housing,
wherein insulating magnetic particles are dispersed in the liquid, and
an orientation of the insulating magnetic particles is changed by controlling a direction of a magnetic field applied by the magnetic field generating member to control the thermal conductivity of the housing.

2. The system according to claim 1, further comprising:
a current supply unit that applies current to the magnetic field generating member,
wherein the current supply unit applies the current in a forward direction to orient the insulating magnetic particles or applies the current in a reverse direction to release the orientation of the insulating magnetic particles.

3. The system according to claim 1, wherein, as the magnetic field generating member, at least one selected from a group consisting of: a winding type solenoid, a linear type solenoid, and a loop type solenoid is used.

4. The system according to claim 1, wherein the insulating magnetic particles are ellipsoidal magnetic particles coated with electrical insulation-type thermal conductive particles on their surfaces.

5. The system according to claim 1,
wherein the liquid is a silicone oil, and
the insulating magnetic particles are made by coating surfaces of any one selected from a group consisting of: ion (Fe), cobalt (Co), and nickel (Ni) with any one selected from a group consisting of: boron nitride, alumina, and magnesium oxide.
